(19) United States
(12) Patent Application Publication
(10) Pub. No.: US 2005/0040432 A1
(43) Pub. Date: Feb. 24, 2005

(54) Light emitting device and method

(75) Inventors: Milton Feng, Champaign, IL (US); Nick Holonyak JR., Urbana, IL (US); Walid Hafez, Champaign, IL (US)

Correspondence Address: Martin Novack, 16355 Vintage Oaks Lane, Delray Beach, FL, 33484, US

(73) Assignee: The Board Of Trustees Of The University Of Illinois

(21) Appl. No.: 10/646,457

(22) Filed: Aug. 22, 2003

(51) Int. Cl. H01L 31/0328

(52) U.S. Cl. 257/198

(57) ABSTRACT

A method for producing controllable light emission from a semiconductor device includes the following steps: providing a heterojunction bipolar transistor device that includes collector, base, and emitter regions; and applying electrical signals across terminals coupled with the collector, base, and emitter regions to cause light emission by radiative recombination in the base region. In a disclosed embodiment, the step of applying electrical signals includes applying a collector-to-emitter voltage and modulating light output by applying a modulating base current.

### FIELD OF THE INVENTION

This invention relates to semiconductor light emission, and, more particularly to a method and device for producing controlled light emission, and which is also simultaneously capable of electrical signal amplification.

### BACKGROUND OF THE INVENTION

A part of the background hereof lies in the development of light emitters based on direct bandgap semiconductors such as III-V semiconductors. Such devices, including light emitting diodes and laser diodes, are in widespread commercial use.

Another part of the background hereof lies in the development of wide bandgap semiconductors to achieve high minority carrier injection efficiency in a device known as a heterojunction bipolar transistor (HBT), which was first proposed in 1948 (see e.g. U.S. Pat. No. 2,569,376; see also H. Kroemer, “Theory Of A Wide-Gap Emitter For Transistors” Proceedings Of The IRE, 45, 1535-1544 (1957)). These transistor devices are capable of operation at extremely high speeds. An InP HBT has recently been demonstrated to exhibit operation at a speed above 500 GHz.

It is among the objects of the present invention to provide devices and methods for producting controlled light emission, and to also provide devices capable of simultaneous control of optical and electrical outputs.

### SUMMARY OF THE INVENTION

An aspect of the present invention involves a direct bandgap heterojunction transistor that exhibits light emission from the base layer. Modulation of the base current produces modulated light emission. [As used herein, “light” means optical radiation that can be within or outside the visible range.]

A further aspect of the invention involves three port operation of a light emitting HBT. Both spontaneous light emission and electrical signal output are modulated by a signal applied to the base of the HBT.

In accordance with one embodiment of the invention, a method is set forth for producing controllable light emission from a semiconductor device, including the following steps: providing a heterojunction bipolar transistor device that includes collector, base, and emitter regions; and applying electrical signals across terminals coupled with the collector, base, and emitter regions to cause light emission by radiative recombination in the base region. In a form of this embodiment, the step of applying electrical signals includes applying a collector-to-emitter voltage and modulating light output by applying a modulating base current.

In accordance with another embodiment of the invention, a device is set forth having an input port for receiving an electrical input signal, an electrical output port for outputting an electrical signal modulated by the input signal, and an optical output port for outputting an optical signal modulated by the input signal, the device comprising a heterojunction bipolar transistor device that includes collector, base, and emitter regions, the input port comprising an electrode coupled with the base region, the electrical output port comprising electrodes coupled with the collector and emitter regions, and the optical output port comprising an optical coupling with the base region.

In accordance with a further embodiment of the invention, a semiconductor laser is set forth, including: a heterojunction bipolar transistor structure comprising collector, base, and emitter of direct bandgap semiconductor materials; an optical resonant cavity enclosing at least a portion of the transistor structure; and means for coupling electrical signals with the collector, base, and emitter regions to cause laser emission from the device.

Further features and advantages of the invention will become more readily apparent from the following detailed description when taken in conjunction with the accompanying drawings.

### BRIEF DESCRIPTION OF THE DRAWINGS

FIG. 1 is a simplified cross-sectional diagram, not to scale, of a device in accordance with the invention, and which can be used in practicing an embodiment of the method of the invention.

FIG. 2 is a top view of the FIG. 1 device layout for an embodiment of the invention.

FIG. 3 is CCD microscopic view of a test device in accordance with the invention.

FIG. 4 is a simplified schematic diagram of a three port device in accordance with an embodiment of the invention.

FIG. 5 is a graph of the common emitter output characteristics of the test device, also showing the observed light emission.

FIG. 6, which includes oscilloscope traces 6A and 6B, show, respectively, the input reference and output modulated light waveforms for the test device.

FIG. 7 is a graph showing light output as a function of base current for the test device.

FIG. 8 illustrates an embodiment of the invention that includes a light reflector.

FIG. 9 illustrates a laser device in accordance with an embodiment of the invention.

FIG. 10A shows a portion of a device in accordance with an embodiment of the invention, employing one or more quantum wells.

FIG. 10B shows a portion of a device in accordance with an embodiment of the invention, employing one or more regions of quantum dots.

FIG. 11 is a simplified cross-sectional diagram, not to scale, of a vertical cavity surface emitting laser in accordance with an embodiment of the invention.

FIG. 12 is a simplified cross-sectional diagram, not to scale, of a vertical cavity surface emitting laser in accordance with a further embodiment of the invention.

FIG. 13 is a simplified diagram of a display array in accordance with an embodiment of the invention.

### DETAILED DESCRIPTION

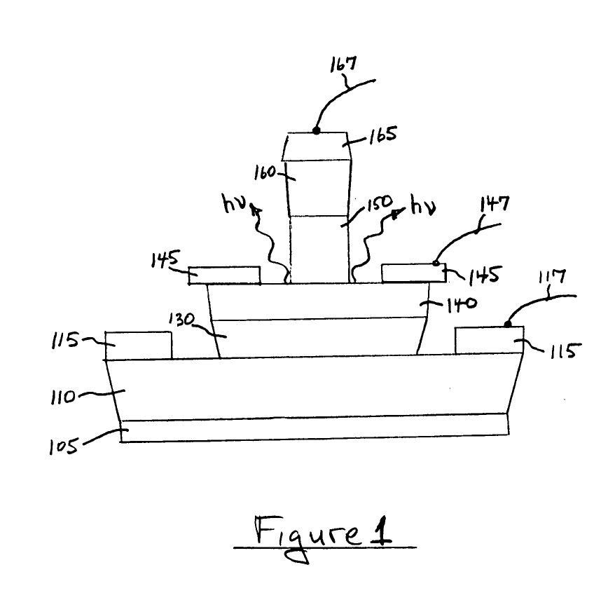

FIG. 1 illustrates a device in accordance with an embodiment of the invention and which can be used in practicing an embodiment of the method of the invention. A substrate 105 is provided, and the following layers are disposed thereon: subcollector 110, collector 130, base 140, emitter 150, and cap layer 160. Also shown are collector metallization (or electrode) 115, base metallization 145, and emitter metallization 165. Collector lead 117, base lead 147, and emitter lead 167 are also shown. In a form of this embodiment, the layers are grown by MOCVD, and the collector layer 130 comprises 3000 Angstrom thick n-type GaAs, n=2×10¹⁶ cm⁻³, the base layer 140 comprises 600 Angstrom thick p+carbon-doped compositionally graded InGaAs (1.4% In), p=4.5×10¹⁹ cm⁻³, the emitter layer 150 comprises 800 Angstrom thick n-type InGaP, n=5×10¹⁷ cm³, and the cap layer comprises 1000 Angstrom thick n+ InGaAs, n=3×10¹⁹ cm⁻³.

This embodiment employs a fabrication process sequence which includes e-beam defined Ti/Pt/Au emitter contacts (145), a self-aligned emitter etch, a self-aligned Ti/Pt/Au base metal deposition, a base-collector etch, and collector metal deposition. A bisbenzocyclobutene (BCB) based etch-back process is employed for “backend” fabrication (i.e., to render the electrode and contact formation on the top of the transistor).

For conventional PN junction diode operation, the recombination process is based on both an electron injected from the n-side and a hole injected from the p-side, which in a bimolecular recombination process can be limited in speed. In the case of HBT light emission hereof, the base “hole” concentration is so high that when an electron is injected into the base, it recombines (bimolecular) rapidly. The base current merely re-supplies holes via relaxation to neutralize charge imbalance. For a heterojunction bipolar transistor (HBT), the base current can be classified into seven components, namely: (1) hole injection into the emitter region (i_{Bp}); (2) surface recombination current in the exposed extrinsic base region (i_{Bsurf}); (3) base ohmic contact recombination current (i_{Bcont}); (4) space charge recombination current (i_{Bscr}); (5) bulk base non-radiative recombination current due to the Hall-Shockley-Reed process (HSR) (i_{BHSR}); (6) bulk base Auger recombination current (i_{BAug}); and (7) bulk base radiative recombination current (i_{Brad}).

For a relatively efficient HBT with ledge passivation on any exposed base region, the surface recombination current can be reduced significantly. Hence, the base current and recombination lifetime can be approximated as primarily bulk HSR recombination, the Auger process, and radiative recombination. The base current expressed in the following equation (1) is then related to excess minority carriers, Δn, in the neutral base region, the emitter area, A_{E}, the charge, q, and the base recombination lifetime, τₙ as
i_{B}=I_{BHSR}+I_{BAUG}+i_{Brad}=qA_{E} Δₙτₙ (1)
The overall base recombination lifetime, τₙ, is related to the separate recombination components of Hall-Shockley-Read, τ_{HSR}, Auger, τ_{AUG}, and radiative recombination, τ_{rad}, as
τₙ=(1/τ_{HSR}+1/τ_{AUG}+1/τ_{rad})⁻¹ (2)

The light emission intensity Δl in the base is proportional to i_{Brad} and is related to the minority carrier electron with the majority hole over the intrinsic carrier concentration, (np-nᵢ²), in the neutral base region and the rate of radiative recombination process, B₁ set forth in Equation (3) below, where the hole concentration can be approximated as equal to base dopant concentration, N_{B}. The radiative base current espressed in equation (3) is then related to excess minority carriers, Δn, in the neutral base region, and the base recombination lifetime, τ_{rad} as
_{Brad}=q A_{E}B(np−nᵢ²)=q A_{E}B n p=q A_{E}Δn(BN_{B})=qA_{E}Δn/τ_{rad} (3)

For a high speed HBT, it is easy to predict that the base recombination lifetime can be less than half of the total response delay time. Hence, the optical recombination process in the base should be at least two times faster than the speed of the HBT. In other words, HBT speed, which can be extremely fast, is limiting.

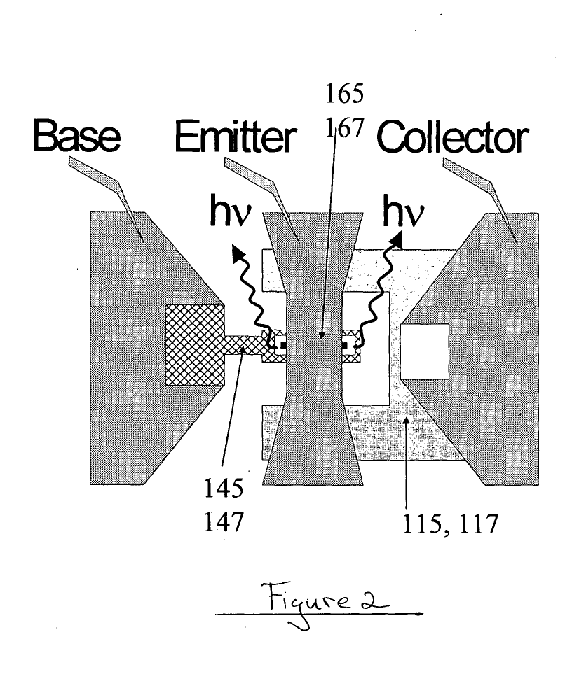

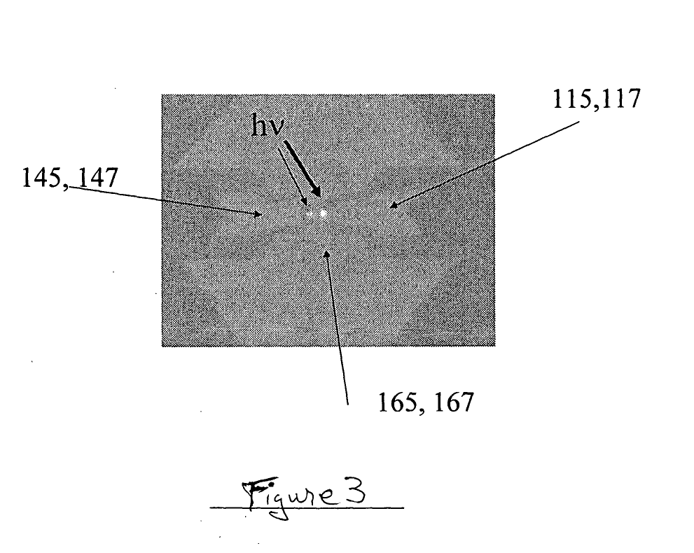

FIG. 2 shows the top view of the device layout and FIG. 3 shows a silicon CCD microscopic view of a fabricated 1×16 μm² HBT test device with light emission (white spots) from the base layer under normal operation of the transistor.

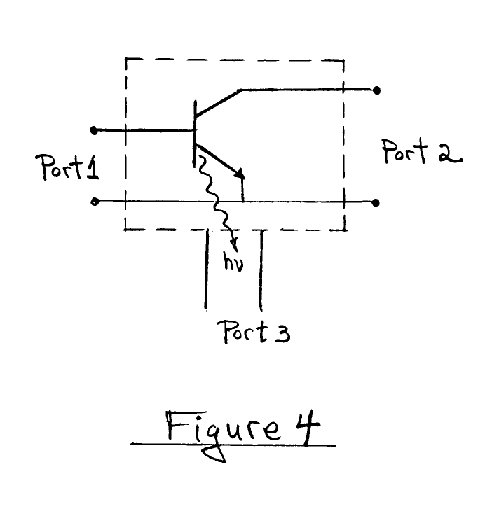

In typical transistor operation, one of the three terminals of a transistor is common to both the input and output circuits. This leads to familiar configurations known as common emitter (CE), common base (CB), and common collector (CC). The common terminal (often ground reference) can be paired with one or the other of the two remaining terminals. Each pair is called a port, and two pairs for any configurations are called a two-port network. The two ports are usually identified as an input port and as an output port. In accordance with a feature hereof as illustrated in FIG. 4, a third port, namely an optical output port, is provided, and is based on (recombination-radiation) emission from the base layer of the HBT light emitter in accordance with an embodiment of the invention. For the HBT of FIG. 1 operated, for example, with a common emitter configuration (see FIG. 4) when an electrical signal is applied to the input port (Port 1), there results simultaneously an electrical output with signal amplification at Port 2 and optical output with signal modulation of light emission at Port 3.

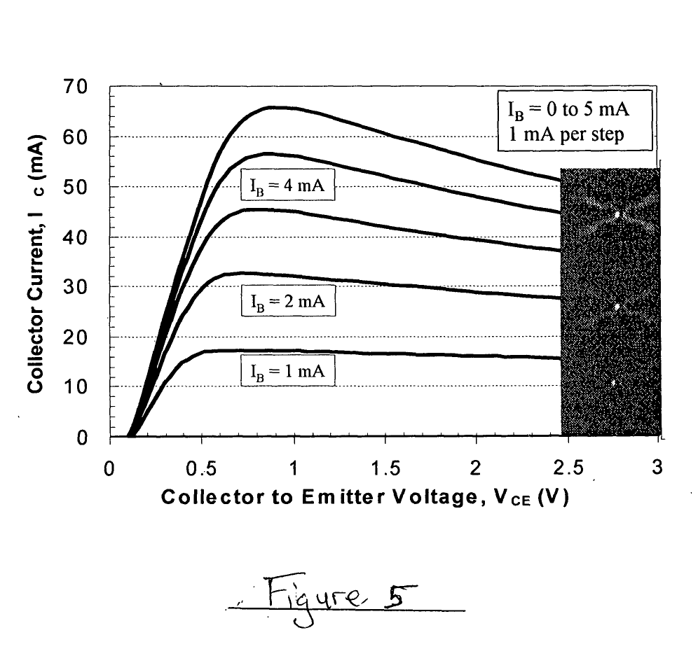

The common emitter output characteristics of the test version of the FIG. 1, 2 device are shown in FIG. 5. The DC beta gain β=17 at i_{b}=1 mA. For i_{b}=0 mA (i_{c}=0 mA), no light emission is observed using a silicon CCD detector. For i_{b}=1 mA (i_{c}=17.3 mA), weak light emission is observed from the base layer. For i_{b}=2 mA (i_{c}=33 mA), stronger light emission is observed, and still stronger for i_{b}=4 mA (i_{c}=57 mA). The spontaneous light emission because of radiative recombination in the base of the HBT in transistor operation is evident.

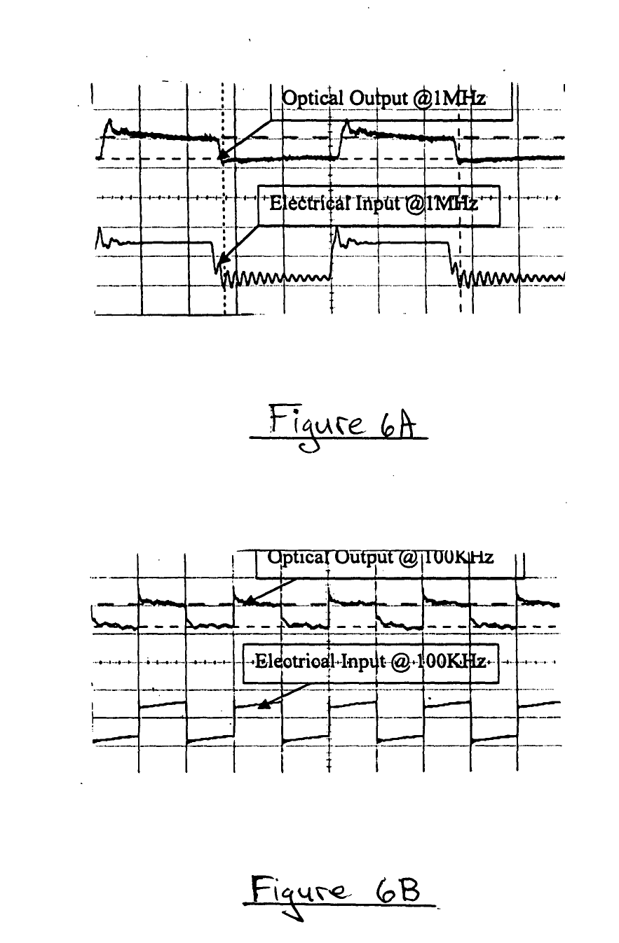

An output light modulation test was performed for this embodiment. A pattern generator (Tektronix Function Generator) produces an AC signal with peak-to-peak amplitude of 1 V. A bias tee combines this AC signal with a DC bias voltage of 1.1V from a DC supply. The InGaP/GaAs HBT turn-on voltage is V_{BE}=1.5V. The HBT transistor's emission area (open space of the base region) is less than 1-μm×2-μm. The light from the small aperture (most of the HBT light is obscured in this test) is coupled into a multimode fiber probe with a core diameter of 25 μm. The light is fed into a Si APD detector with a 20-dB linear amplifier. A sampling oscilloscope displays both the input modulation signal and the output light signal. The optical emission wavelength is around 885 nm due to the compositionally graded InGaAs base (1.4% In). FIG. 6 shows the input (lower trace) reference and output (upper trace) light waveforms when the HBT is modulated at 1 MHz (FIG. 6A) and also at 100 KHz (FIG. 6B). The output signal has a peak-to-peak amplitude of 375 μV at 1 MHz and 400 μV at 100 KHz. These data show that the output light signal tracks the input signal, showing clearly that the HBT is a light-emitting transistor (LET) that operates at transistor speed.

The output peak-to-peak amplitude, Vₚₚ, which is directly proportional to the light emission intensity, Δlₒᵤₜ, as a function of base current, is shown in FIG. 7. The nonlinear behavior may be due to beta compression because of heating and the fact that the device geometry has not yet been optimized for light emission (as well as lateral biasing effects). Nevertheless, these measurements, i.e., Δlₒᵤₜ (light intensity) vs. Δi_{b} (i_{b}=0 to 5 mA), demonstrate the HBT as a three terminal controllable light source.

It will be understood that other configurations and material systems can be used, including, as examples, GaAs and GaN based HBTs, or other direct bandgap material systems.

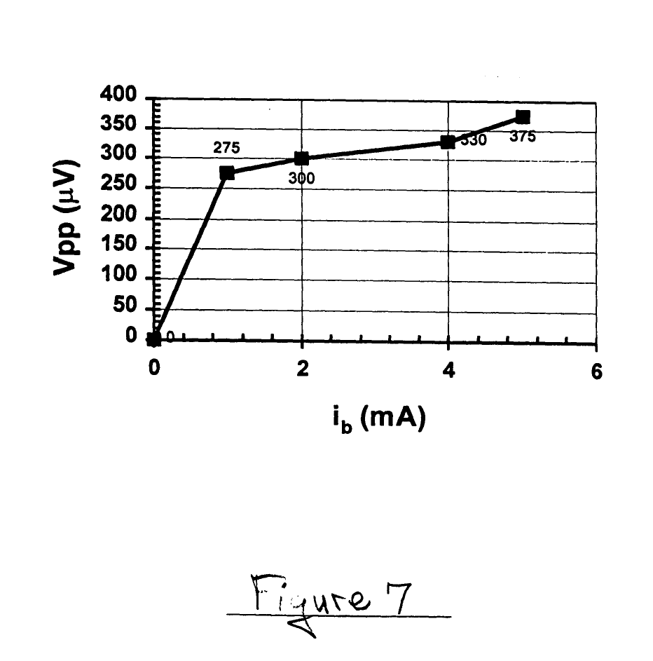

FIG. 8 illustrates use of the three terminal light emitting HBT 810 in conjunction with a reflector cup 820 for enhancing light collection and directionality.

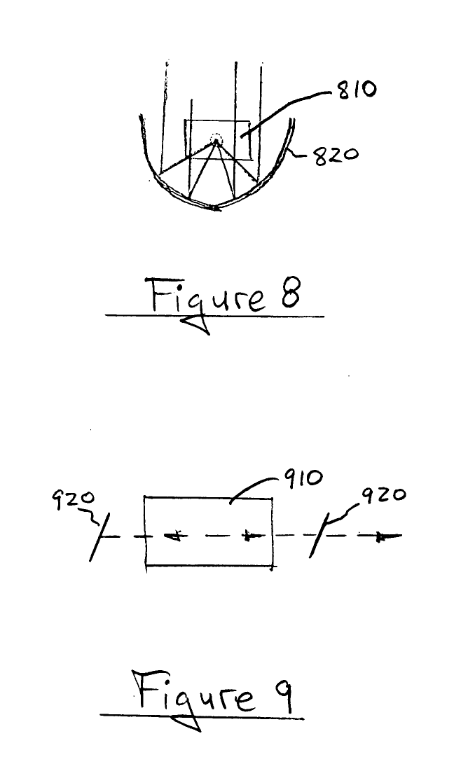

FIG. 9 illustrates the three terminal light emitting HBT, 910, in a lateral cavity, represented at 920, for operation as a lateral gain guided laser. The lateral cavity may be defined, for example, by cleaved edges on and near the light emitting region.

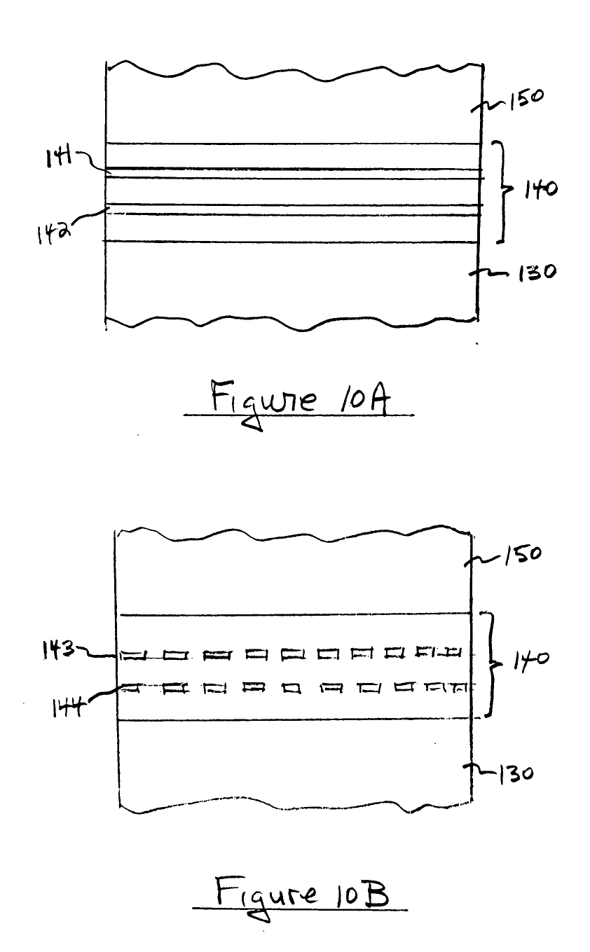

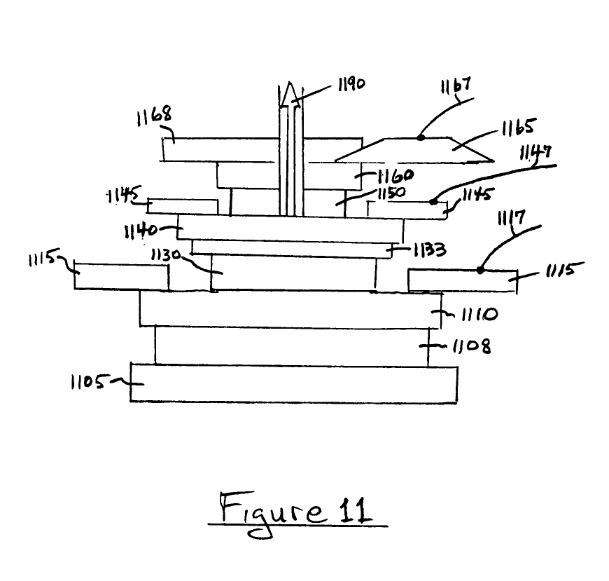

FIG. 10A shows the use of one or more quantum wells, 141, 142, in the base region 140 of the FIG. 1 device (or other embodiments), these quantum wells being operative to enhance the recombination process for improved modulation and/or to tailor the spectral characteristics of the device.

FIG. 10B shows use of one or more regions of quantum dots, 143, 144, in the base region 140 of the FIG. 1 device (or other embodiments), these quantum dot regions being operative to enhance the recombination process for improved modulation and/or to tailor the spectral characteristics of the device.

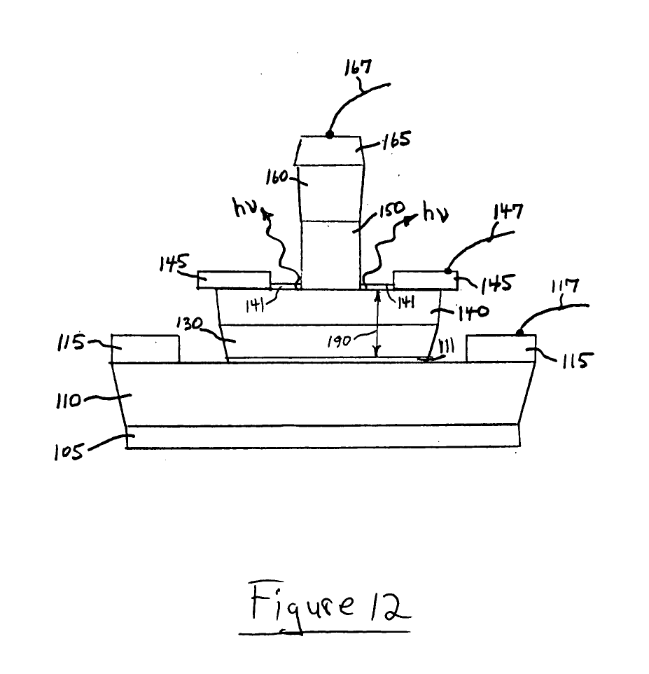

FIG. 11 shows a vertical cavity surface emitting laser in accordance with an embodiment of the invention which employs light emission from the base region of an HBT. A substrate 1105 is provided, and the following layers are provided thereon. DBR reflector layer 1108, subcollector 1110, collector 1130, transition layer 1133, base 1140, emitter 1150, emitter cap layer 1160 and top DBR reflector layer 1168. Also shown are collector metallization 1115, base metallization 1145, and emitter metallization 1165. Collector lead 1117, base lead 1147, and emitter lead 1167 are also shown. In a form of this embodiment, the layers are grown by MOCVD, the substrate 1105 is a semi-insulating InP substrate, subcollector 1110 is n+ InGaAs, collector 1130 is n− InP, the base 1140 is a p+InGaAs layer with a quantum well, the emitter 1150 is n-type InP, and the emitter cap 1160 is n+ InGaAs. Also, the transition layer is an n-type quaternary transition layer, for example InGaAsP. In this embodiment, the reflector layers 1108 and 1168 are multiple layer DBR reflectors, which can be spaced apart by suitable distance, such as a half wavelength. In operation, as before, with signals applied in three terminal mode, modulation of the base current produces modulated light emission, in this case vertically emitted laser light represented by arrow 1190. As above, it will be understood that other configurations and material systems can be used, including, as examples, GaAs and GaN based HBTs, or other direct bandgap material systems.

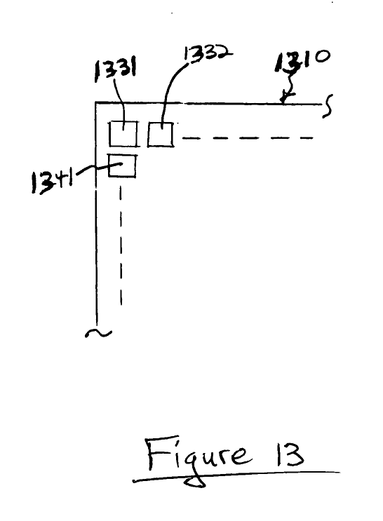

FIG. 12 shows a further embodiment of a vertical cavity surface emitting laser, which has a Bragg reflector as close as possible to the collector and with elimination of intervening lower gap absorbing layers between the DBRs. In particular, in FIG. 12 (which has like reference numerals to FIG. 1 for corresponding elements), the lower DBR is shown at 111, and an upper DBR is shown at 141. Arrow 190 represents the optical standing wave of the VCSEL. The DBR 141 can be a deposited Si-SiO₂ Bragg reflector. A further reflector can also be provided on the top of emitter 150.

FIG. 13 shows a display 1310 using an array of light-emitting HBTs 1331, 1332, 1341, etc. The light output intensities can be controlled, as previously described. Very high speed operation can be achieved.

The principles hereof can also potentially have application to indirect bandgap materials (such as Ge and Si) in an HBT with a heavily doped base region, and with an optical port that is optically coupled with the base region. The light produced will generally be of less intensity than that produced by the direct bandgap HBT light emitters hereof. However, it may be useful to have this light generating and coupling capability in Ge-Si systems for various applications, including devices having one or more quantum wells and/or one or more quantum dot regions for enhancing recombination.

1. A method for producing controllable light emission from a semiconductor device, comprising the steps of:
providing a heterojunction bipolar transistor device that includes collector, base, and emitter regions; and
applying electrical signals across terminals coupled with said collector, base, and emitter regions to cause light emission by radiative recombination in the base region.

2. The method as defined by claim 1, wherein said step of applying electrical signals includes applying a collector-to-emitter voltage and modulating light output by applying a modulating base current.

3. The method as defined by claim 2, wherein said modulating base current is applied at a frequency of at least 1 MHz.

4. The method as defined by claim 3, wherein said step of applying signals includes applying an emitter-to-base forward bias and base-to-collector reverse bias.

5. The method as defined by claim 1, wherein said step of providing a heterojunction bipolar transistor device comprises providing a device formed of direct bandgap materials.

6. The method as defined by claim 2, wherein said step of providing a heterojunction bipolar transistor device comprises providing a device formed of direct bandgap materials.

7. The method as defined by claim 1, wherein said step of applying electrical signals to cause light emission includes applying base current to produce light emission that is substantially proportional to the applied base current.

8. The method as defined by claim 2, wherein said step of applying electrical signals to cause light emission includes applying base current to produce light emission that is substantially proportional to the applied base current.

9. The method as defined by claim 5, wherein said step of applying electrical signals to cause light emission includes applying base current to produce light emission that is substantially proportional to the applied base current.

10. The method as defined by claim 1, wherein said step of providing a heterojunction bipolar transistor device comprises providing said device with a heavily doped base region.

11. The method as defined by claim 6, wherein said step of providing a heterojunction bipolar transistor device comprises providing said device with a heavily doped base region.

12. The method as defined by claim 8, wherein said step of providing a heterojunction bipolar transistor device comprises providing said device with a heavily doped base region.

13. The method as defined by claim 1, wherein said step of providing a heterojunction bipolar transistor device comprises providing said device with a heavily doped p-type base region.

14. The method as defined by claim 1, further comprising providing a laser cavity on said device to obtain laser emission.

15. The method as defined by claim 5, further comprising providing a laser cavity on said device to obtain laser emission.

16. A device having an input port for receiving an electrical input signal, an electrical output port for outputting an electrical signal modulated by said input signal, and an optical output port for outputting an optical signal modulated by said input signal, said device comprising a heterojunction bipolar transistor device that includes collector, base, and emitter regions, said input port comprising an electrode coupled with said base region, said electrical output port comprising electrodes coupled with said collector and emitter regions, and said optical output port comprising an optical coupling with said base region.

17. The device as defined by claim 16, wherein said heterojunction bipolar transistor device comprises regions of direct bandgap semiconductor material.

18. The device as defined by claim 16, wherein said input port comprises electrodes coupled with the base and emitter regions of said device, and said output electrical port comprises electrodes coupled with the collector and emitter regions of said device.

19. The device as defined by claim 16, wherein said input port comprises electrodes coupled with the base and emitter regions of said device, and said output electrical port comprises electrodes coupled with the collector and emitter regions of said device.

20. A semiconductor laser, comprising:
a heterojunction bipolar transistor structure comprising collector, base, and emitter of direct bandgap semiconductor materials;
an optical resonant cavity enclosing at least a portion of said transistor structure; and
means for coupling electrical signals with said collector, base, and emitter regions to cause laser emission from said device.

21. The laser as defined by claim 20, wherein at least a portion of said heterojunction transistor structure is in layered form, and wherein said optical resonant cavity is a lateral cavity with respect to the layer plane of said at least a portion of said structure.

22. The laser as defined by claim 20, wherein at least a portion of said heterojunction transistor structure is in layered form, and wherein said optical resonant cavity is a vertical cavity with respect to the layer plane of said at least a portion of said structure.

23. The laser as defined by claim 20, wherein said heterojunction bipolar transistor structure comprises an InP-based device.

24. The laser as defined by claim 20, wherein said heterojunction bipolar transistor structure comprises a GaAs-based device.

25. The laser as defined by claim 20, wherein said heterojunction bipolar transistor structure comprises a GaN-based device.

26. A semiconductor device for producing controllable light emission, comprising:
a heterojunction bipolar transistor structure comprising collector, base, and emitter of direct bandgap semiconductor materials;
at least one quantum well disposed in the base region; and
means for coupling electrical signals with said collector, base, and emitter regions to cause light emission from said device by radiative recombination in the base region.

27. The device as defined by claim 26, further comprising an optical resonant cavity enclosing at least a portion of said transistor structure.

28. The device as defined by claim 26, wherein said means for coupling electrical signals includes means for applying a collector-to-emitter voltage and for modulating light output with applied base current.

29. The device as defined by claim 27, wherein said means for coupling electrical signals includes means for applying a collector-to-emitter voltage and for modulating light output with applied base current.

30. A method for producing light modulated with an input electrical signal, comprising the steps of:
providing a heterostructure bipolar transistor device that includes collector, base, and emitter regions of direct bandgap semiconductor materials, said base region being heavily doped;
applying electrical signals to said collector, base, and emitter regions to cause light emission by radiative recombination in the base region; and
controlling the base current of said transistor device with said input electrical signal to modulate the light emission from said transistor device.

31. The method as defined by claim 30, wherein said input electrical signal includes frequencies of at least 1 MHz.

32. The method as defined by claim 30, wherein said step of applying signals includes applying an emitter-to-base forward bias and base-to-collector reverse bias.

33. The method as defined by claim 30, wherein said step of applying electrical signals to cause light emission includes applying base current to produce light emission that is substantially proportional to the applied base current.

34. A method for producing an electrical output modulated with an input signal and for producing light modulated with said input electrical signal, comprising the steps of:
providing a heterostructure bipolar transistor device that includes collector, base, and emitter regions of direct bandgap semiconductor materials, said base region being heavily doped;
applying electrical signals to said collector, base, and emitter regions to cause light emission by radiative recombination in the base region; and
controlling the base current of said transistor device with said input electrical signal to modulate an electric output signal of said device and to modulate the light emission from said transistor device.

35. The method as defined by claim 34, wherein said step of applying signals includes applying an emitter-to-base forward bias and base-to-collector reverse bias.

36. The method as defined by claim 34, wherein said step of applying electrical signals to cause light emission includes applying base current to produce light emission that is substantially proportional to the applied base current.

37. A display, comprising:
an array of heterojunction bipolar transistor devices that include collector, base, and emitter regions of direct bandgap semiconductor materials; and
means for applying electrical signals across terminals coupled with said collector, base, and emitter regions of said devices to cause light emission by radiative recombination in the base regions of said devices.

38. The display as defined by claim 37, wherein said means for applying signals includes modulating the light output of individual devices of the array by applying signals that control the base currents of said devices.

39. An optoelectronic method, comprising the steps of:
providing a heterojunction bipolar transistor device that includes collector, base, and emitter regions;
applying electrical signals across terminals coupled with said collector, base, and emitter regions to cause light emission by radiative recombination in the base region; and
providing an optical coupling to the light emitted from said base region.

40. The method as defined by claim 39, wherein said step of applying electrical signals includes applying a collector-to-emitter voltage and modulating light output by applying a modulating base current.

41. The method as defined by claim 39, wherein said step of providing a heterojunction bipolar transistor device comprises providing a device formed of direct bandgap materials.

42. The method as defined by claim 39, wherein said step of providing a heterojunction bipolar transistor device comprises providing a device formed of indirect bandgap materials.

43. The method as defined by claim 39, wherein said step of applying electrical signals to cause light emission includes applying base current to produce light emission that is substantially proportional to the applied base current.

44. The method as defined by claim 41, wherein said step of providing a heterojunction bipolar transistor includes providing at least one quantum well layer in the base region of said heterojunction bipolar transistor.

45. The method as defined by claim 42, wherein said step of providing a heterojunction bipolar transistor includes providing at least one quantum well layer in the base region of said heterojunction bipolar transistor.

46. The method as defined by claim 41, wherein said step of providing a heterojunction bipolar transistor includes providing at least one quantum dot region in the base region of said heterojunction bipolar transistor.

47. The method as defined by claim 42, wherein said step of providing a heterojunction bipolar transistor includes providing at least one quantum dot region in the base region of said heterojunction bipolar transistor.
